(19) United States
(12) Patent Application Publication
(10) Pub. No.: US 2025/0338064 A1
(43) Pub. Date: Oct. 30, 2025

(54) AREA-EFFICIENT AND LOW-COST SPEAKER PROTECTION IMPEDANCE MEASUREMENT AND CALIBRATION

(71) Applicant: QUALCOMM Incorporated, San Diego, CA (US)

(72) Inventors: Ramkumar SIVAKUMAR, San Diego, CA (US); Yin Min HTAY, Singapore (SG); Yuen Loong WONG, Singapore (SG); Sherif GALAL, Irvine, CA (US)

(21) Appl. No.: 18/650,695

(22) Filed: Apr. 30, 2024

(51) Int. Cl. H04R 3/04; G01R 27/16; H04R 29/00

(52) U.S. Cl. CPC H04R 3/04; G01R 27/16; H04R 29/001

(57) ABSTRACT

A speaker impedance measurement includes a test phase and a measurement phase. In the measurement phase, an output amplifier drives a speaker with an output voltage and an output current. A first amplifier amplifies the output voltage to produce a first output signal. A second amplifier amplifies a sense resistor voltage from a sense resistor conducting the output current to produce second output signal. A processor measures the speaker impedance responsive to a function of the first and second output signals, ideal gains of the first and second amplifiers, and an at least one calibration factor. During the test phase, the at least one calibration factor is calculated with respect to a calibration load.

### TECHNICAL FIELD

The present application relates generally to speaker protection and, more specifically, to an area-efficient and low-cost speaker protection impedance measurement and calibration.

### BACKGROUND

Consumers prefer that their mobile devices have improved sound quality and fidelity. An important factor in meeting this need is an impedance measurement (R0) of the absolute value of the real component of the speaker load at room temperature. For example, a manufacturer may measure the speaker impedance during manufacture to determine whether a speaker meets quality specifications before shipping. An audio driver of the speaker may also use the speaker impedance to estimate the speaker coil temperature. Should the speaker coil temperature be excessive as determined through an impedance measurement, the audio driver may reduce the delivered power to the speaker to avoid coil damage. In addition, the audio driver may use the speaker impedance measurement to estimate excursion of the speaker diaphragm based upon the power delivered. In this fashion, the audio driver may maximize the power delivery to the speaker while preventing speaker damage.

### SUMMARY

In accordance with an aspect of the disclosure, an audio system is provided that includes: an output amplifier configured to amplify an audio input signal to drive a speaker with an output voltage and an output current; a first amplifier configured to amplify an output voltage of the output amplifier to form a first output signal; a first analog-to-digital converter configured to convert the first output signal into a first digital signal; a sense resistor configured to conduct an output current of the output amplifier to develop a sense resistor voltage across the sense resistor; a second amplifier configured to amplify the sense resistor voltage to form a second output signal; a second analog-to-digital converter configured to convert the second output signal into a second digital signal; and a processor configured to determine an impedance of the speaker responsive to the first digital signal, the second digital signal, and at least one correction factor that accounts for a difference between an actual gain and an ideal gain of each of the first amplifier and the second amplifier.

In accordance with another aspect of the disclosure, a method of calibrating an audio system is provided that includes: amplifying a first input signal in an output amplifier to produce an output voltage and an output current while the output amplifier drives a calibration load; measuring the output voltage to provide a measure of the output voltage; amplifying the output voltage in a first amplifier to form a first output signal; determining an actual gain of the first amplifier responsive to the first output signal and the measure of the output voltage; conducting the output current through a sense resistor to develop a sense resistor voltage; amplifying the sense resistor voltage in a second amplifier to form a second output signal; determining an actual gain of the second amplifier responsive to the second output signal and the measure of the output voltage; and calculating an at least one calibration code responsive to a difference between the actual gain of the first amplifier and an ideal gain of the first amplifier and responsive to a difference between the actual gain of the second amplifier and the ideal gain of the second amplifier.

In accordance with yet another aspect of the disclosure, a method of measuring a speaker impedance is provided that includes: amplifying an audio input signal in an output amplifier to produce an output voltage and an output current while the output amplifier drives a speaker; amplifying the output voltage in a first amplifier; to form a first output signal; conducting the output current through a sense resistor to develop a sense resistor voltage; amplifying the sense resistor voltage in a second amplifier to form a second output signal; and calculating the speaker impedance responsive to the first output signal, the second output signal, and at least one correction factor that accounts for a difference between an actual gain and an ideal gain of each of the first amplifier and the second amplifier.

These and other advantageous features may be better appreciated through the following detailed description.

### BRIEF DESCRIPTION OF THE DRAWINGS

FIG. 1 is a diagram of an example audio system configured to implement a speaker impedance measurement algorithm in accordance with an aspect of the disclosure.

FIG. 2 is a flowchart summarizing a test phase portion of a speaker impedance measurement algorithm in accordance with an aspect of the disclosure.

FIG. 3 is a flowchart summarizing a measurement phase portion of a speaker impedance measurement algorithm in accordance with an aspect of the disclosure.

FIG. 4 is a more detailed flowchart of the test phase portion of the speaker impedance measurement algorithm in accordance with an aspect of the disclosure.

FIG. 5 is a more detailed flowchart of the measurement phase portion of the speaker impedance measurement algorithm in accordance with an aspect of the disclosure.

FIG. 6 illustrates some example electronic audio systems configured to implement a speaker impedance measurement in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

A speaker impedance algorithm is disclosed for an audio system that may be practiced by any suitable processor. In the following discussion, it will be assumed that the processor is a digital signal processor (DSP) that generates an audio input signal for an output amplifier that drives the speaker, but it will be appreciated that other types of processors may implement the speaker impedance algorithm. The output amplifier converts the audio input signal into an output voltage and an output current to drive the speaker. As given by Ohm's law, the speaker impedance (R0) equals the output voltage divided by the output current.

The output amplifier may be included into an audio system including an audio front end. To assist the speaker impedance algorithm, the audio front end may include a voltage amplifier for amplifying the output voltage into an amplified output voltage and also include a first analog-to-digital converter (ADC) for converting the amplified output voltage into a digital output signal denoted as Vsense that may be received by the DSP. For sensing the output current, the audio front end may include a sense resistor that conducts the output current to develop a sense resistor voltage. The audio front end may further include a current amplifier for amplifying the sense resistor voltage into an amplified sense resistor voltage and include a second ADC for converting the amplified sense resistor voltage into a digital output signal denoted as Isense_V that may be received by the DSP. The “_V” portion of Isense_V is used because this signal represents the sense resistor voltage as opposed to the output current. The output current is thus proportional to Isense_V divided by the sense resistor resistance (Rsense).

The output amplifier has some output gain with respect to amplifying the audio input signal to produce the output voltage and output current. Regardless of the value of this output gain, the output gain does not affect the speaker impedance measurement since the speaker impedance is proportional to the output voltage divided by the output current (the output gain being cancelled by the division). However, the gain of the voltage and current amplifiers will generally affect the speaker impedance measurement. In that regard, note that due to the amplification by the output amplifier to produce the output voltage, the amplification by the voltage amplifier will typically be a negative gain whereas the amplification by the current amplifier will typically be a positive gain. The voltage amplifier may be designed to provide a desired or ideal gain (Vgain_ideal) but in practice will have some actual gain that varies from this ideal value due to real-world inaccuracies and variabilities. Similarly, the current amplifier may be designed to provide a desired or ideal gain (Igain_ideal) but in practice will have some actual gain that varies from this ideal value.

If the voltage and current amplifiers were ideal, a measurement of the speaker impedance (R0) would be relatively straightforward. In particular, the output voltage will equal a ratio of Vsense/Vgain_ideal. Similarly, the output current equals the ratio (Isense_V/(Igain_ideal*Rsense), where the division by the resistance (Rsense) of the sense resistor converts the sense resistor voltage to the output current. Since the speaker impedance R0 equals the output voltage divided by the output current, the speaker impedance R0 in an ideal case may thus be expressed by the following Equation (1):

$$R 0 = ( Vsense * Igain\_ideal * Rsense ) / ( Isense\_V * Vgain\_ideal ) \qquad Eq . ( 1 )$$

But due to real-world non-idealities, the gains of the voltage and current amplifiers will typically vary from their ideal values as noted earlier. In addition, the resistance Rsense of the sense resistor will vary from its desired or ideal value. As a result of these variations, the use of Equation (1) to calculate the speaker impedance R0 may result in errors as large as (or larger) than 30% from the actual impedance. This measurement error will be advantageously reduced such as to 1% or less as discussed herein by accounting for the actual gains of the voltage and current amplifiers. With respect to this characterization, the audio front end and the DSP may be integrated into a single integrated circuit or be in separate integrated circuits. Regardless of their relative integration with respect to each other, the audio front end and the DSP are eventually integrated into a system such as a mobile device (for example, a cellular telephone or a laptop) that includes a speaker driven by the audio front end through a pair of output terminals. Prior to this integration with the speaker, a calibration load and a measurement meter may be coupled to the pair of output terminals such as by mounting the audio front end and the DSP into a test fixture. As will be explained further herein, the departure from the ideal gains for the voltage and current amplifiers may then be characterized so that an accurate measurement of the speaker impedance may be performed after the audio system is integrated into the final product with the speaker. There are thus two phases to the speaker impedance measurement algorithm: a calibration phase and a measurement phase. The calibration phase occurs prior to the manufacture of the mobile device including the speaker. The measurement phase occurs after manufacture of the mobile device. Although the final product is denoted as a mobile device in the following discussion, it will be appreciated that the speaker impedance measurement algorithm may be performed by non-mobile devices in addition to mobile devices such as a cellular telephone, a tablet, or a laptop.

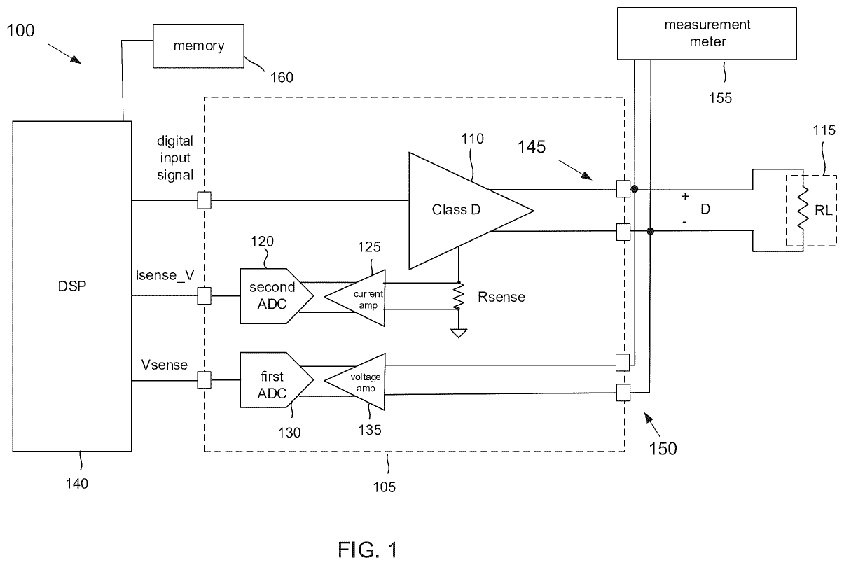

An example audio system 100 that may perform this advantageous speaker impedance characterization will now be discussed in more detail with respect to FIG. 1. An audio front end 105 includes an output amplifier 110 that amplifies an audio input signal from a DSP 140 to drive a pair of output terminals 145 with an amplified output signal. Prior to the integration of the audio front end 105 into a mobile device that includes a speaker coupled to the pair of output terminals 145, an external measurement meter 155 may be coupled to the pair of output terminals 145. In addition, a calibration resistor RL having a known calibration resistance may be coupled to the pair of output terminals 145. The output amplifier 110 is configured to provide a gain G. In the following discussion, it will be assumed that the output amplifier 110 is a class-D amplifier, but it will be appreciated that other classes of output amplifiers may be used in alternative implementations. The gain G may be 18 dB in one implementation, but it will be appreciated that higher or lower gains may be used in alternative implementations. The root mean square (RMS) value of the output signal voltage will thus be denoted as D in the following discussion since it is produced by the class-D output amplifier 110. During the calibration phase, the output amplifier 110 drives the amplified output signal D through the calibration resistor RL while the measurement meter 155 measures D. However, it will be appreciated that instead of measuring the RMS output voltage, the RMS output current may be measured in alternative implementations of the calibration phase.

The output signal voltage from the output amplifier 110 also couples through a pair of input terminals 150 in the audio front end 105 to a voltage amplifier 135. As discussed previously, the voltage amplifier 135 has an ideal gain of Vgain_ideal but will vary from this gain due to real-world non-idealities. Because of the relatively large gain G from the output amplifier 110, the gain from the voltage amplifier 135 may be negative. In one implementation, this ideal gain (Vgain_ideal) may be −21 dB, but it will be appreciated that higher or lower voltage amplifier gains may be used in alternative implementations. A first ADC 130 digitizes an output signal from the voltage amplifier 35 to output Vsense to the DSP 140.

The output current from the output amplifier 110 conducts through a sense resistor Rsense to ground. The current sense resistor Rsense may have a relatively low sense resistance for improved efficiency. In one example implementation, the sense resistance may be 0.1Ω. This is its ideal or desired resistance, but the sense resistance will typically vary from this ideal value due to real-world non-idealities. A current amplifier 125 amplifies a voltage across the sense resistor Rsense to sense the sense resistor voltage. A second ADC 120 digitizes an output signal from the current amplifier 125 to provide Isense_V to the DSP 140. In one implementation, an ideal gain (Igain_ideal) of the current amplifier 125 may be 15 dB, but it will be appreciated that a higher or lower gain may be used in alternative implementations. Note that the Isense digital output signal actually represents the sense resistor voltage, but it may be converted to the output current by dividing by the sense resistance.

The preceding test phase may be modified in implementations in which the gain of the output amplifier 110 may be assumed to be accurately known. In such implementations, the RMS output voltage D may be determined merely by multiplying the digital input signal by the known gain of the output amplifier 110. The measurement meter 115 is thus optional for the test phase.

Following the test phase, the audio system 100 is integrated into a mobile device. The measurement meter 155 and the calibration resistor RL are replaced with a speaker 115 as part of the completion of the mobile device. During normal operation, if the DSP 140 would then characterize the speaker impedance R0 using Equation (1) as discussed earlier, the resulting impedance measurement may be subject to considerable error due to the departure from the ideal gains in the amplifiers 125 and 135. But the measurement of the RMS output voltage D during the test phase is advantageously exploited to characterize the non-idealities of the current amplifier 125, the voltage amplifier 135, and of the sense resistance. For example, the speaker impedance algorithm disclosed herein may determine a voltage gain correction factor (V_corr) such the test phase such that D equals (Vsense*V_corr)/Vgain_ideal. Similarly, the speaker impedance algorithm determines a current gain correction factor (I_corr) such that the output current equals (Isense_V*I_corr)/(I gain_ideal*Rsense). With the correction factors the speaker impedance R0 in a real-world case is thus given by the following Equation (2):

$$R 0 = ( Vsense * Igain\_ideal * Rsense * V\_corr ( Isense\_V * Vgain\_ideal * I\_corr ) \qquad Eq . ( 2 )$$

To calculate the voltage gain correction factor V_corr during the test phase, the DSP 140 may be configured to set the digital input signal to some known value such as measured through decibels relative to full scale (dBFS). With the measurement meter 155 and the calibration resistor RL (which may also be denoted as a calibration load) coupled across the pair of output terminals 145, the factors D, Vsense, and Isense_V are measured. Assuming that the gains are all characterized in decibels, an actual gain (Vgain_real) of the voltage amplifier 135 thus equals Vsense-D. A difference between Vgain_real and Vgain_ideal may be expressed as a percentage error (Vsense GEA) according to the following Equation (3):

$$Vsense GEA = ( ( Vgain\_real - Vgain\_ideal ) / Vgain\_real ) * 100 \qquad Eq . ( 3 )$$

In some implementations, the expected percentage error Vsense GEA may be expected to range from +/−30% although it will be appreciated that the speaker impedance algorithm disclosed herein may be adapted to smaller or larger error ranges. Given this expected error range, the Vsense percentage gain error Vsense GEA may be expected to range from −30% to 30%. A voltage gain calibration code (Cal Code V) may then be calculated depending upon the desired resolution. In one implementation, a one percent error equals a voltage gain calibration code of 4 although a higher or coarse code resolution may be used in alternative implementations. Given this 0.25 resolution and the expected gain error range, the voltage gain calibration code will range from −120 to +120. An eight-bit wide resolution for the voltage gain calibration code will thus be sufficient to cover this range with one of the bits being a sign bit. For example, the most-significant bit may be the sign bit and the remaining seven least significant bits encoding the magnitude of the voltage gain error. With the voltage gain calibration code calculated during the test phase such as by the DSP 140, it may be stored in a non-volatile memory such as a fuse memory 160.

The gain error of the current amplifier may be characterized in an analogous fashion. As noted earlier, the RMS output voltage D and Isense_V are measured during the test phase with the measurement meter 155 and the calibration resistor RL coupled across the pair of output terminals 145. An actual gain (Igain_real) of the current amplifier 125 may thus be characterized as Isense_V−D. To convert from voltage to the output current, a calibration ideal gain (Igain_ideal_cal) is determined that equals 20*log 10(Rsense/RL)+Igain_ideal, where Rsense is the sense resistance and RL is the calibration resistor resistance, and log is an abbreviation of the logarithm function. A difference between the ideal and real gains may then be calculated such as a percentage error (Isense GEA) between Igain_real and Igain_ideal_cal for the current amplifier 125. The percentage error Isense GEA may be expressed according to the following Equation (4):

$$Isense GEA = ( ( Igain\_real - Igain\_ideal \_cal ) / Igain\_real ) * 100 \qquad Eq . ( 4 )$$

A current gain calibration code (Cal Code I) may then be calculated that equals (Isense GEA)/0.25 although a finer or coarser code resolution may be used in alternative implementations. In one implementation, an eight-bit wide resolution for the current gain calibration code will be sufficient to cover the expected error range for the current gain with one of the bits being a sign bit. For example, the most-significant bit may be the sign bit and the remaining seven least significant bits encoding the magnitude of the voltage gain error. With the current gain calibration code calculated during the test phase such as by the DSP 140, it may then be stored in a non-volatile memory such as the fuse memory 160. The voltage gain calibration code is also denoted herein as a first digital code. Similarly, the current gain calibration code is also denoted herein as a second digital code.

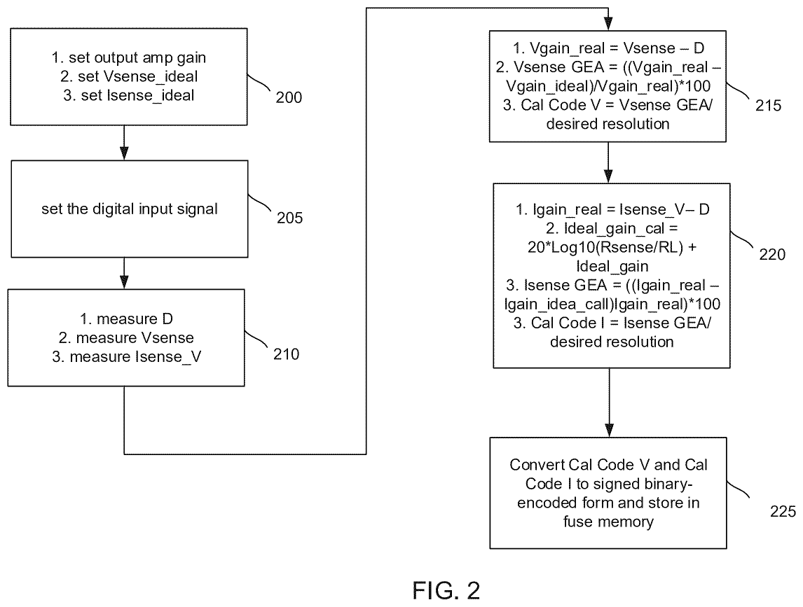

An example process flow for the test phase may now be summarized with respect to the flowchart of FIG. 2. In a step 200, the output amplifier 110 is configured to provide a desired gain. Similarly, the voltage and current gains Vgain_ideal and Igain_ideal are set in step 200. For example, these gains may be set through corresponding resistance values. In a step 205, the DSP 140 is configured to set a magnitude for the digital input signal. With these preceding factors known, the RMS output voltage D may be measured in a step 210 along with Vsense and Isense_V. In a step 215, Vgain_real is calculated as Vsense−D. With Vgain_real determined, Vsense GEA may be determined as discussed for Equation (3). Depending upon the desired code resolution, the voltage calibration code (Cal Code V) may then be determined by dividing Vsense GEA by the desired resolution. For example, if a 1% error is desired to code to 4 bits, the desired resolution is 0.25 such that the voltage calibration code equals Vsense GEA/0.25.

In a step 220, Igain_real is calculated as Isense_V−D. With Igain_real determined, Isense GEA may be determined as discussed for Equation (4). Depending upon the desired code resolution, the current calibration code (Cal Code I) may then be determined by dividing Isense GEA by the desired resolution. Finally, in a step 225 the calibration codes are converted into a signed binary-encoded form and stored in a non-volatile memory in the audio system.

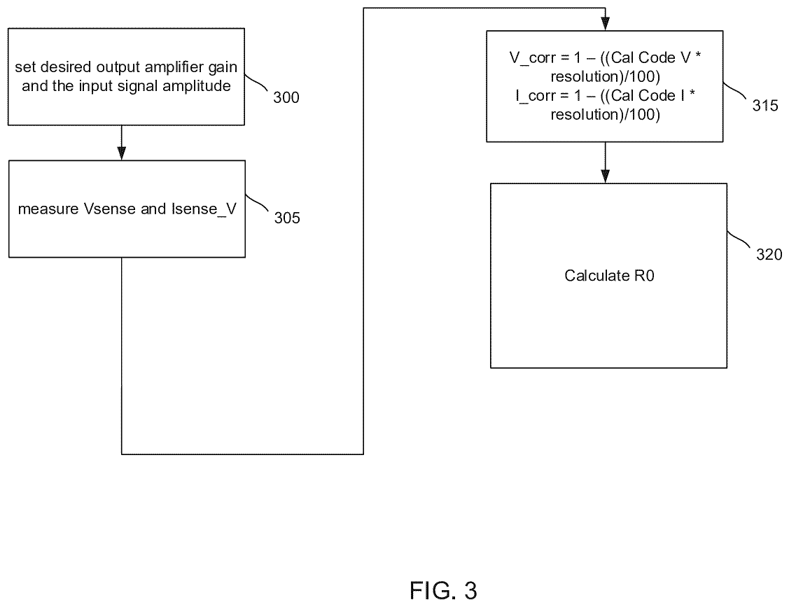

The preceding test phase occurs prior to manufacture of the mobile device. Following the test phase, the measurement meter 155 and the calibration resistor are decoupled from the pair of output terminals 145 and replaced by the speaker 115. With the mobile device completed such that the speaker 115 is coupled to the pair of output terminals 145, regular operation may ensue in which speaker impedance R0 is determined during the measurement phase. An example process flow for the measurement phase is shown in the flowchart of FIG. 3. The measurement phase begins with a step 300 of setting the desired output amplifier gain and the input signal amplitude. The ideal gains of the current amplifier 125 and the voltage amplifier 135 may also be set in step 300. In a step 305, Vsense and Isense_V are measured. With Vsense measured, V_corr may be calculated in a step 310 by retrieving the voltage calibration code Cal Code V from memory 160 and subtracting the product of (Cal Code V*resolution)/100 from one. Similarly, I_corr may be calculated in step 310 by retrieving the current calibration code Cal Code I from memory 160 and subtracting the product (Cal Code I*resolution)/100 from one. The speaker impedance R0 may then be calculated in a step 320 using Equation (2) discussed earlier. The audio system 100 may proceed to use the speaker impedance R0 measurement in a number of advantageous fashions. For example, the audio system 100 may determine a quality of the speaker from the speaker impedance R0. Alternatively, the audio system 100 may determine a speaker temperature or diaphragm excursion from the speaker impedance R0.

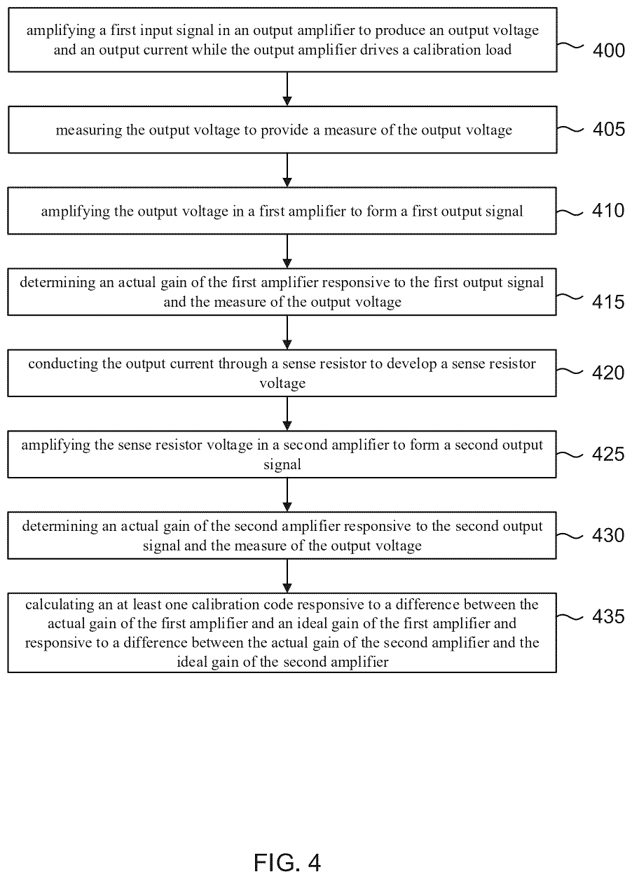

A method of performing the test phase will now be summarized in more detail with respect to the flowchart of FIG. 4. The method includes an act 400 of amplifying a first input signal in an output amplifier to produce an output voltage and an output current while the output amplifier drives a calibration load. The amplification of a digital input signal by the output amplifier 110 while the pair of output terminals 145 are coupled to the calibration load RL is an example of act 400. The method also includes an act 405 of measuring the output voltage to provide a measure of the output voltage. The measurement of the RMS output voltage D by the measurement meter 155 is an example of act 405. In addition, the method includes an act 410 of amplifying the output voltage in a first amplifier to form a first output signal. The amplification of the RMS output voltage D by the voltage amplifier 135 is an example of act 410. The method also includes an act 415 of determining an actual gain of the first amplifier responsive to the first output signal and the measure of the output voltage. The determination of Vgain_real is an example of act 415. An act 420 includes conducting the output current through a sense resistor to develop a sense resistor voltage. The conduction through the sense resistor Rsense is an example of act 420. An act 425 includes amplifying the sense resistor voltage in a second amplifier to form a second output signal. The amplification by the current amplifier 125 is an example of act 425. The method also includes an act 430 of determining an actual gain of the second amplifier responsive to the second output signal and the measure of the output voltage. The determination of Igain_real is an example of act 430. Finally, the method includes an act 435 of calculating an at least one calibration code responsive to a difference between the actual gain of the first amplifier and an ideal gain of the first amplifier and responsive to a difference between the actual gain of the second amplifier and the ideal gain of the second amplifier. It may be seen from Equation (2) that the ratio of the voltage and current gain calibration factors may be used to form a single combined calibration code (an at least one calibration code). Thus, the calculation of the voltage and current calibration codes is an example of act 435.

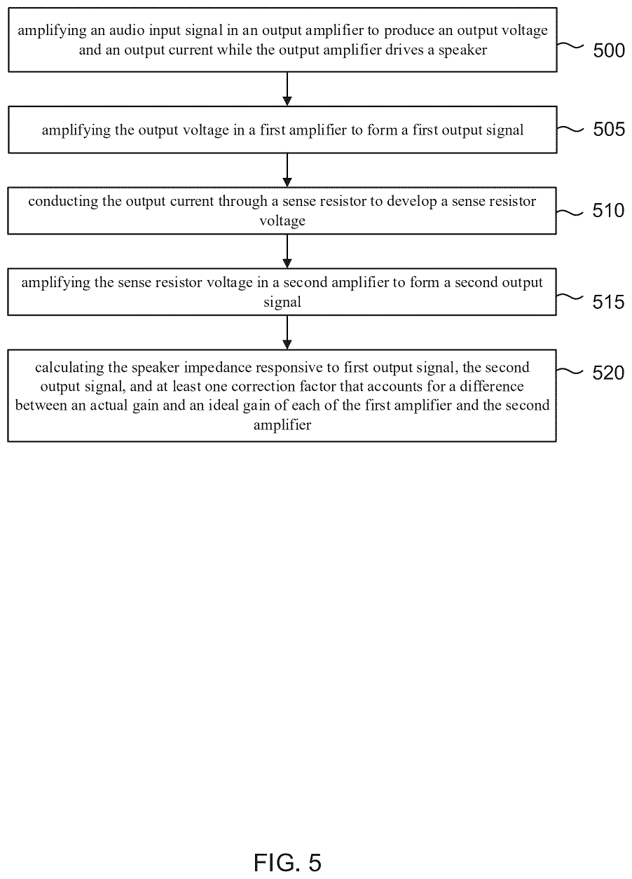

A method of performing the measurement phase will now be discussed in more detail with respect to the flowchart of FIG. 5. The method includes an act 500 of amplifying an audio input signal in an output amplifier to produce an output voltage and an output current while the output amplifier drives a speaker. The amplifying of the audio input signal in the output amplifier 110 while driving the speaker 115 is an example of act 500. The method also includes an act 505 of amplifying the output voltage in a first amplifier to form a first output signal. The amplification of the output voltage in the voltage amplifier 135 is an example of act 505. An act 510 comprises conducting the output current through a sense resistor to develop a sense resistor voltage. The conduction through the sense resistor Rsense is an example of act 510. In addition, the method includes an act 515 of amplifying the sense resistor voltage in a second amplifier to form a second output signal. The amplification by the current amplifier 125 is an example of act 515. Finally, the method includes an act 520 of calculating the speaker impedance responsive to the first output signal, the second output signal, and at least one correction factor that accounts for a difference between an actual gain and an ideal gain of each of the first amplifier and the second amplifier. The calculation of R0 using Equation (2) is an example of act 520.

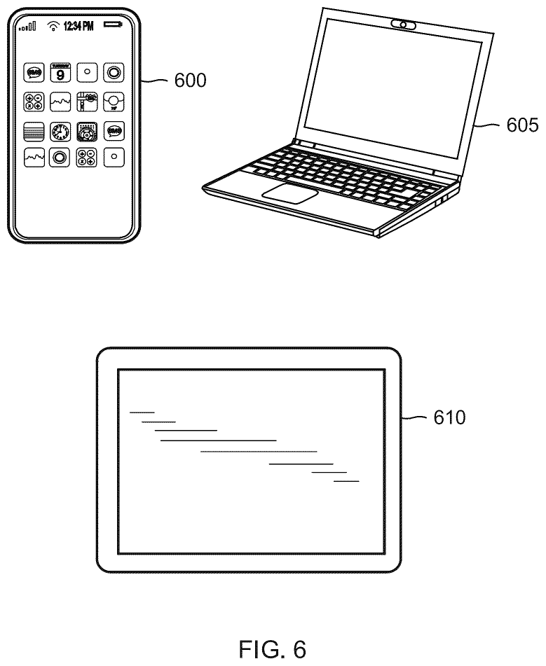

An audio system as disclosed herein may be incorporated in a wide variety of electronic systems. For example, as shown in FIG. 6, a cellular telephone 600, a laptop computer 605, and a tablet 610 may all include an audio system configured to measure a speaker impedance in accordance with the disclosure. Other exemplary electronic systems such as a video player, a communication device, and a personal computer may also be configured with an audio system constructed in accordance with the disclosure.

Some example implementations are described by the following numbered clauses:

Clause 1. An audio system, comprising:
an output amplifier configured to amplify an audio input signal to drive a speaker with an output voltage and an output current;
a first amplifier configured to amplify an output voltage of the output amplifier to form a first output signal;
a first analog-to-digital converter configured to convert the first output signal into a first digital signal;
a sense resistor configured to conduct an output current of the output amplifier to develop a sense resistor voltage across the sense resistor;
a second amplifier configured to amplify the sense resistor voltage to form a second output signal;
a second analog-to-digital converter configured to convert the second output signal into a second digital signal; and
a processor configured to determine an impedance of the speaker responsive to the first digital signal, the second digital signal, and at least one correction factor that accounts for a difference between an actual gain and an ideal gain of each of the first amplifier and the second amplifier.

Clause 2. The audio system of clause 1, wherein the processor comprises a digital signal processor.

Clause 3. The audio system of clause 2, wherein the digital signal processor is further configured to generate the audio input signal.

Clause 4. The audio system of any of clauses 1-3, wherein the at least one correction factor comprises a first correction factor that is proportional to a difference between the actual gain and the ideal gain of the first amplifier and comprises a second correction factor that is proportional to a difference between the actual gain and the ideal gain of the second amplifier.

Clause 5. The audio system of clause 4, further comprising:
a non-volatile memory configured to store the first correction factor and the second correction factor.

Clause 6. The audio system of clause 5, wherein the non-volatile memory comprises a fuse memory.

Clause 7. The audio system of any of clauses 4-6, wherein the processor is further configured to determine the impedance of the speaker responsive to a product of the first digital signal, the ideal gain of the first amplifier, a resistance of the sense resistor, and the first correction factor divided by a product of the second digital signal, the ideal gain of the second amplifier, and the second correction factor.

Clause 8. The audio system of any of clauses 4-7, wherein the first correction factor comprises a first digital code including a first sign bit, and wherein the second correction factor comprises a second digital code including a second sign bit.

Clause 9. The audio system of clause 8, wherein the first sign bit and the second sign bit each comprises a most-significant bit.

Clause 10. The audio system of any of clauses 1-9, wherein the output amplifier comprises a class-D output amplifier.

Clause 11. The audio system of any of clauses 1-10, wherein the audio system is included within a cellular telephone.

Clause 12. A method of calibrating an audio system, comprising:
amplifying a first input signal in an output amplifier to produce an output voltage and an output current while the output amplifier drives a calibration load;
measuring the output voltage to provide a measure of the output voltage;
amplifying the output voltage in a first amplifier to form a first output signal;
determining an actual gain of the first amplifier responsive to the first output signal and the measure of the output voltage;
conducting the output current through a sense resistor to develop a sense resistor voltage;
amplifying the sense resistor voltage in a second amplifier to form a second output signal;
determining an actual gain of the second amplifier responsive to the second output signal and the measure of the output voltage; and
calculating an at least one calibration code responsive to a difference between the actual gain of the first amplifier and an ideal gain of the first amplifier and responsive to a difference between the actual gain of the second amplifier and the ideal gain of the second amplifier.

Clause 13. The method of clause 12, wherein calculating the at least one calibration code is further responsive to a function of a ratio of a resistance of the sense resistor to a resistance of the calibration load.

Clause 14. The method of clause 13, wherein the function is a logarithm of the ratio of the resistance of the sense resistor to the resistance of the calibration load.

Clause 15. The method of any of clauses 12-14, further comprising storing the at least one calibration code in a non-volatile memory.

Clause 16. A method of measuring a speaker impedance, comprising:
amplifying an audio input signal in an output amplifier to produce an output voltage and an output current while the output amplifier drives a speaker;
amplifying the output voltage in a first amplifier to form a first output signal;
conducting the output current through a sense resistor to develop a sense resistor voltage;
amplifying the sense resistor voltage in a second amplifier to form a second output signal; and
calculating the speaker impedance responsive to the first output signal, the second output signal, and at least one correction factor that accounts for a difference between an actual gain and an ideal gain of each of the first amplifier and the second amplifier.

Clause 17. The method of clause 16, further comprising:
digitizing the first output signal to form a first digital signal; and
digitizing the second output signal to form a second digital signal, wherein measuring the speaker impedance is further responsive to the first digital signal and the second digital signal.

Clause 18. The method of clause 17, wherein the at least one correction factor comprises a first correction factor that is proportional to a difference between the actual gain and the ideal gain of the first amplifier and comprises a second correction factor that is proportional to a difference between the actual gain and the ideal gain of the second amplifier, and wherein measuring the speaker impedance comprises dividing a product of the first digital signal, the ideal gain of the first amplifier, a resistance of the sense resistor, and the first correction factor with a product of the second digital signal, the ideal gain of the second amplifier, and the second correction factor.

19. The method of clause 18, wherein the first digital signal, the second digital signal, the ideal gain of the first amplifier, the ideal gain of the second amplifier, the resistance of the sense resistor, the first correction factor, and the second correction factor are all expressed in decibels.

Clause 20. The method of any of clauses 16-19, further comprising:
determining a quality of the speaker from the speaker impedance.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. An audio system, comprising:
an output amplifier configured to amplify an audio input signal to drive a speaker with an output voltage and an output current;
a first amplifier configured to amplify an output voltage of the output amplifier to form a first output signal;
a first analog-to-digital converter configured to convert the first output signal into a first digital signal;
a sense resistor configured to conduct an output current of the output amplifier to develop a sense resistor voltage across the sense resistor;
a second amplifier configured to amplify the sense resistor voltage to form a second output signal;
a second analog-to-digital converter configured to convert the second output signal into a second digital signal; and
a processor configured to determine an impedance of the speaker responsive to the first digital signal, the second digital signal, and at least one correction factor that accounts for a difference between an actual gain and an ideal gain of each of the first amplifier and the second amplifier.

2. The audio system of claim 1, wherein the processor comprises a digital signal processor.

3. The audio system of claim 2, wherein the digital signal processor is further configured to generate the audio input signal.

4. The audio system of claim 1, wherein the at least one correction factor comprises a first correction factor that is proportional to a difference between the actual gain and the ideal gain of the first amplifier and comprises a second correction factor that is proportional to a difference between the actual gain and the ideal gain of the second amplifier.

5. The audio system of claim 4, further comprising:
a non-volatile memory configured to store the first correction factor and the second correction factor.

6. The audio system of claim 5, wherein the non-volatile memory comprises a fuse memory.

7. The audio system of claim 4, wherein the processor is further configured to determine the impedance of the speaker responsive to a product of the first digital signal, the ideal gain of the first amplifier, a resistance of the sense resistor, and the first correction factor divided by a product of the second digital signal, the ideal gain of the second amplifier, and the second correction factor.

8. The audio system of claim 4, wherein the first correction factor comprises a first digital code including a first sign bit, and wherein the second correction factor comprises a second digital code including a second sign bit.

9. The audio system of claim 8, wherein the first sign bit and the second sign bit each comprises a most-significant bit.

10. The audio system of claim 1, wherein the output amplifier comprises a class-D output amplifier.

11. The audio system of claim 1, wherein the audio system is included within a cellular telephone.

12. A method of calibrating an audio system, comprising:
amplifying a first input signal in an output amplifier to produce an output voltage and an output current while the output amplifier drives a calibration load;
measuring the output voltage to provide a measure of the output voltage;
amplifying the output voltage in a first amplifier to form a first output signal;
determining an actual gain of the first amplifier responsive to the first output signal and the measure of the output voltage;
conducting the output current through a sense resistor to develop a sense resistor voltage;
amplifying the sense resistor voltage in a second amplifier to form a second output signal;
determining an actual gain of the second amplifier responsive to the second output signal and the measure of the output voltage; and
calculating an at least one calibration code responsive to a difference between the actual gain of the first amplifier and an ideal gain of the first amplifier and responsive to a difference between the actual gain of the second amplifier and the ideal gain of the second amplifier.

13. The method of claim 12, wherein calculating the at least one calibration code is further responsive to a function of a ratio of a resistance of the sense resistor to a resistance of the calibration load.

14. The method of claim 13, wherein the function is a logarithm of the ratio of the resistance of the sense resistor to the resistance of the calibration load.

15. The method of claim 12, further comprising storing the at least one calibration code in a non-volatile memory.

16. A method of measuring a speaker impedance, comprising:
amplifying an audio input signal in an output amplifier to produce an output voltage and an output current while the output amplifier drives a speaker;
amplifying the output voltage in a first amplifier to form a first output signal;
conducting the output current through a sense resistor to develop a sense resistor voltage;
amplifying the sense resistor voltage in a second amplifier to form a second output signal; and
calculating the speaker impedance responsive to the first output signal, the second output signal, and at least one correction factor that accounts for a difference between an actual gain and an ideal gain of each of the first amplifier and the second amplifier.

17. The method of claim 16, further comprising:
digitizing the first output signal to form a first digital signal; and
digitizing the second output signal to form a second digital signal, wherein measuring the speaker impedance is further responsive to the first digital signal and the second digital signal.

18. The method of claim 17, wherein the at least one correction factor comprises a first correction factor that is proportional to a difference between the actual gain and the ideal gain of the first amplifier and comprises a second correction factor that is proportional to a difference between the actual gain and the ideal gain of the second amplifier, and wherein measuring the speaker impedance comprises dividing a product of the first digital signal, the ideal gain of the first amplifier, a resistance of the sense resistor, and the first correction factor with a product of the second digital signal, the ideal gain of the second amplifier, and the second correction factor.

19. The method of claim 18, wherein the first digital signal, the second digital signal, the ideal gain of the first amplifier, the ideal gain of the second amplifier, the resistance of the sense resistor, the first correction factor, and the second correction factor are all expressed in decibels.

20. The method of claim 16, further comprising:
determining a quality of the speaker from the speaker impedance.
